(19) United States
(12) Patent Application Publication
(10) Pub. No.: US 2019/0324223 A1
(43) Pub. Date: Oct. 24, 2019

(54) PHOTONIC ENGINE PLATFORM UTILIZING EMBEDDED WAFER LEVEL PACKAGING INTEGRATION

(71) Applicant: Intel Corporation, Santa Clara, CA (US)

(72) Inventors: Myung Jin Yim, San Jose, CA (US); Sang Yup Kim, Sunnyvale, CA (US)

(73) Assignee: Intel Corporation, Santa Clara, CA (US)

(21) Appl. No.: 16/465,003

(22) PCT Filed: Dec. 29, 2016
(86) PCT No.: PCT/US16/69095

§ 371 Date: May 29, 2019

(51) Int. Cl. G02B 6/43; G02B 6/42; G02B 6/12; H01L 21/683; H01L 25/16; H01L 25/18; H01L 23/538; H04B 10/50; H04B 10/60; H01L 23/00

(52) U.S. Cl. CPC G02B 6/43; H01L 2224/16227; G02B 6/12004; G02B 6/4239; H01L 21/6836; H01L 25/167; H01L 25/18; H01L 23/5389; H04B 10/50; H04B 10/60; H01L 24/04; H01L 24/13; H01L 24/16; H01L 2221/68331; H01L 2221/68372; H01L 2224/04105; H01L 2224/12105; H01L 2224/13025; G02B 6/4232

(57) ABSTRACT

Methods/structures of forming package structures are described. Those methods/structures may include a mold material, wherein a plurality of die are embedded in the mold material, a package substrate, wherein the mold material comprising the plurality of die is at least partially embedded in a cavity of the substrate, and wherein a liner is between side and bottom portions of the mold material and the package substrate, at least one optical die disposed on the package substrate, and a thermal solution disposed on a top surface of the optical die.

### BACKGROUND

Increases in connected technologies and growth of large data centers are making increasing demands on bandwidth and transmission speeds. Data centers are increasingly using photons instead of electrons to send data at faster rates between servers, racks, and boards. Adoption of high speed photonic connections between electrical and optical integrated circuits depends on optical module miniaturization, and high volume, low cost fabrication techniques, for example.

### BRIEF DESCRIPTION OF THE DRAWINGS

While the specification concludes with claims particularly pointing out and distinctly claiming certain embodiments, the advantages of these embodiments can be more readily ascertained from the following description when read in conjunction with the accompanying drawings in which:

FIG. 1 represents a side perspective view of structures according to embodiments.

FIG. 2 represents a top view of structures according to embodiments.

FIGS. 3a, 3a′-3o′, and 3b represent cross-sectional view of structures according to embodiments.

FIG. 4 represents a top view of structures according to embodiments.

FIGS. 5a-5m represent cross-sectional views of structures according to embodiments, while FIGS. 5a′, 5g′ and 5l′ represent top views of structures according to embodiments.

FIGS. 6a-d represent cross-sectional views of structures according to embodiments.

FIG. 7 represents a flow chart of a method according to embodiments.

FIG. 8 represents a cross sectional view of a computer system implementing one or more embodiments.

FIG. 9 represents a schematic of a computing device according to embodiments.

### DETAILED DESCRIPTION

In the following detailed description, reference is made to the accompanying drawings that show, by way of illustration, specific embodiments in which the methods and structures may be practiced. These embodiments are described in sufficient detail to enable those skilled in the art to practice the embodiments. It is to be understood that the various embodiments, although different, are not necessarily mutually exclusive. For example, a particular feature, structure, or characteristic described herein, in connection with one embodiment, may be implemented within other embodiments without departing from the spirit and scope of the embodiments. In addition, it is to be understood that the location or arrangement of individual elements within each disclosed embodiment may be modified without departing from the spirit and scope of the embodiments.

The following detailed description is, therefore, not to be taken in a limiting sense, and the scope of the embodiments is defined only by the appended claims, appropriately interpreted, along with the full range of equivalents to which the claims are entitled. In the drawings, like numerals may refer to the same or similar functionality throughout the several views. The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers. Layers and/or structures “adjacent” to one another may or may not have intervening structures/layers between them. A layer(s)/structure(s) that is/are directly on/directly in contact with another layer(s)/structure(s) may have no intervening layer(s)/structure(s) between them.

Various implementations of the embodiments herein may be formed or carried out on a substrate, such as a package substrate. A package substrate may comprise any suitable type of substrate capable of providing electrical communications between a die, such as an integrated circuit (IC) die, and a next-level component to which an IC package may be coupled (e.g., a circuit board). In another embodiment, the substrate may comprise any suitable type of substrate capable of providing electrical communication between an IC die and an upper IC package coupled with a lower IC/die package, and in a further embodiment a substrate may comprise any suitable type of substrate capable of providing electrical communication between an upper IC package and a next-level component to which an IC package is coupled.

A substrate may also provide structural support for a die/device, in the embodiments below. By way of example, in one embodiment, a substrate may comprise a multi-layer substrate—including alternating layers of a dielectric material and metal—built-up around a core layer (either a dielectric or a metal core). In another embodiment, a substrate may comprise a coreless multi-layer substrate. Other types of substrates and substrate materials may also find use with the disclosed embodiments (e.g., ceramics, sapphire, glass, etc.). Further, according to one embodiment, a substrate may comprise alternating layers of dielectric material and metal that are built-up over a die itself—this process is sometimes referred to as a “bumpless build-up process.” Where such an approach is utilized, conductive interconnects may or may not be needed (as the build-up layers may be disposed directly over a die, in some cases).

A die/device may comprise any type of integrated circuit device. In one embodiment, the die may include a processing system (either single core or multi-core). For example, a die may comprise a microprocessor, a graphics processor, a signal processor, a network processor, a chipset, optical die, etc. In one embodiment, a die comprises a system-on-chip (SoC) having multiple functional units (e.g., one or more processing units, one or more graphics units, one or more communications units, one or more signal processing units, one or more security units, etc.). However, it should be understood that the disclosed embodiments are not limited to any particular type or class of device/die.

Embodiments of methods of forming packaging structures, such as integrating an embedded wafer level ball grid array die, with a photonic engine block/platform. Those methods/structures may include The embodiments herein enable the fabrication of a highly integrated optical module comprising a small form factor, with high bandwidth, low power optical interconnection between electrical and optical die/devices/chips.

The increase of connected technologies and growth of big data centers are making even bigger demands on bandwidth and transmission speeds. Photonic connections between optical devices and electronic devices benefit from optics module miniaturization, low power, and high bandwidth, high volume and low cost manufacturing technology advances.

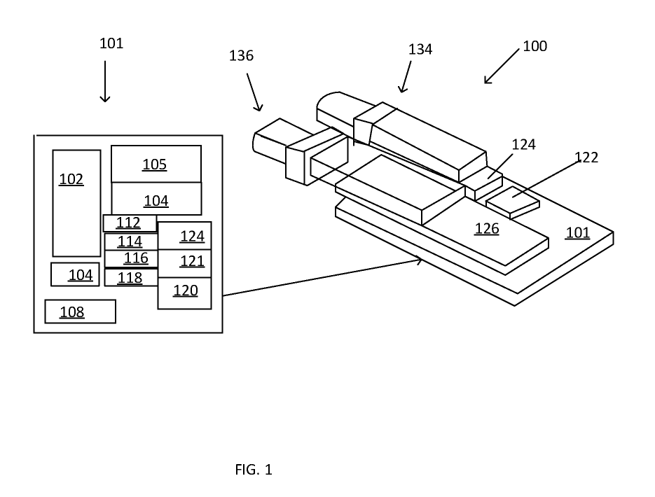

The embodiments herein disclose highly integrated optical modules, possessing a small form factor, which enable high bandwidth and low power optical interconnection between optical and electrical devices/chips within the optical module. Integration is enhanced by employing a modular photonic engine platform. FIGS. 1-9 illustrate embodiments of fabricating an optical assembly utilizing eWLB process techniques. For example, electronic component integrated circuits (IC's)/die, which may be configured as a single system on a chip (SoC) 101, and optical IC's/die, such as Transmission (Tx) die 126 and Receiver (Rx) die 124, may be stacked upon each other, and may share electrical interconnection with each other within a photonic engine block module 100, as depicted in FIG. 1, wherein a perspective view of a universal SoC integration for a photonics engine block 100 is shown. The photonic engine block 100 is capable of integrating electrical Tx/Rx signals and optical Tx/Rx signals within the module 100.

The SoC 101 may comprise a universal IC/die (UIC) 101, and may comprise a modulator driver IC 102, which may comprise a Tx driver, in an embodiment, a transimpedance amplifier (TIA)/limiting amplifier (LA) IC 105, a clock and data recovery (CDR) die 104, a microcontroller die 120, and other die as needed by the particular design requirements. For example, the UIC 101 may additionally comprise an analog to digital converter (ADC) chip/die 124, a laser biasing chip/die 108, a bandgap die 112, a low drop out regulator (LDO) die 114, a clock die 116, flash memory die 121 and a temperature die 118.

In an embodiment, the optoelectronic Tx 126, the optoelectronic Rx 124, and a miscellaneous die 122 or multi die package 122, which could include, but not limited to, memory, MEMS (micro-electo-mechanical systems), crystals, resistors, capacitors, inductors, may be stacked upon the universal chip 101 by employing solder connections such as micro-bumps, including face to face die bonding. The system/module 100 may comprise conductive interconnection structures to physically and electrically couple to a substrate, such as to a printed circuit board (PCB), wherein the coupling may be accomplished through the use of through silicon vias (TSV) coupled to solder bumps that may be disposed on the backside of the UIC. Optical alignment assemblies 134, 136 may be coupled with Rx and Tx optical die respectively. In an embodiment, the photonic engine block 100 may be flexible to support various optical module form factors, such as pluggable, embedded and/or optics co-package integration.

In an embodiment, the universal IC/die may be formed utilizing an embedded wafer level ball grid array (eWLB) process. The eWLB structure may include fan out portions adjacent the individual die within wafer level package structures. The eWLB of the embodiments herein provide high assembly throughput and die level system integration by using wafer level packaging infrastructure. Wafer level redistribution layers (RDL) may be fabricated for high speed electrical connectivity among driver, CDR, and micro-controller die. Pre-assembly testing may be performed for driver, TIA/LA, CDR and microcontroller plus management IC's before these die are coupled with optics die, and/or with further optics assembly/module assembly. The embodiments herein also disclose various process flow steps that enable the integration of a UIC, such as UIC 101 by utilizing eWLB techniques/structures, and integrating optical dice stacking for a final module assembly, such as photonic module/block 100.

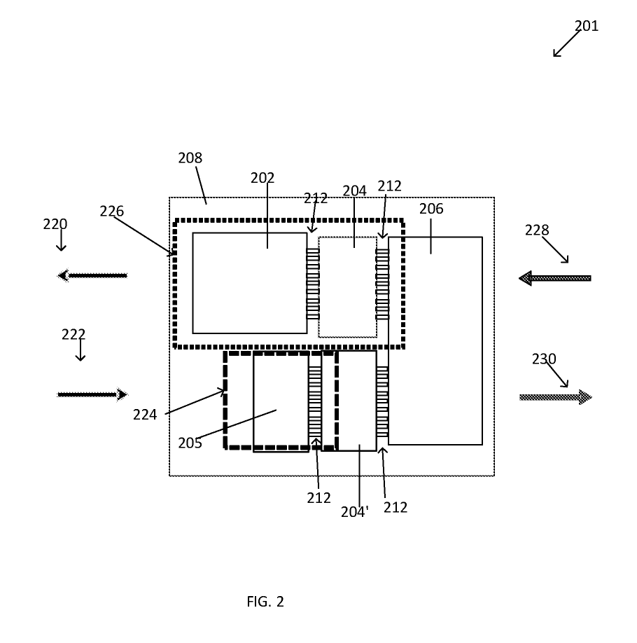

FIG. 2 (top view) depicts eWLB structure 201 (which may comprise a UIC), integration for driver, TIA, Tx/Rx CDR and microcontroller and management IC's, and optionally passive components, within an optical module. In an embodiment, Tx driver 202, Tx CDR 204, microprocessor 206, TIA 205, and Rx CDR 204′ may be on, and in some embodiments embedded, within molding 208, and may be fabricated on heterogeneous semiconductor process nodes. In an embodiment, the Tx die 202 may comprise a 50 Giga bits per second (Gbps) or higher, non return to zero (NRZ) or PAM modulator driver, and may comprise DAC for modulator bias control. In an embodiment, the Tx die 202 may comprise a complementary metal oxide silicon (CMOS) circuit, which may be fabricated in a 28 nm process node, for example. In an embodiment, the Tx CDR 204 may comprise a 50 Gbps, or higher, Tx CDR, and may comprise a silicon germanium circuit fabricated in a Bi-CMOS process node, for example.

In an embodiment, the TIA 205 may comprise a 50 Gbps circuit or higher, and the Rx CDR 204′ may comprise a Bi-CMOS silicon germanium circuit. In an embodiment, the microprocessor 206 may comprise a power management integrated circuit (PMIC) including microcontroller, (MCU), ADC, laser switch router (Lsr) digital to analog converter (DAC) at the 90 nm CMOS node, for example. In an embodiment, an optical Tx die 226 (dotted line) may be attached directly on the Tx driver block/die 202, and at least partially disposed on/over the Tx CDR 204. In an embodiment, an optical Rx die 226 may be attached/electrically coupled to the TIA block/die 205, and may be at least partially disposed on/over the Rx CDR 204′. TIA die 205 may be electrically coupled/interconnected by a redistribution layer (RDL) 212 to Rx CDR die block 204, and Tx CDR blocks 216 may be electrically interconnected to Tx die 202 and to microprocessor 206.

In an embodiment, most, if not all of the electrical connections between die on/embedded in the molding compound 208 may be accomplished by RDL connections, such as between microcontroller and management die 206 within an eWLB structure. The UIC 201 is capable of being coupled with optical Tx signals 220, and optical Rx signals 222. In an embodiment, the UIC/eWLB wafer structure 201 may be coupled with/may interface with electrical Tx signals 228, which may comprise pulse amplitude modulation (PAM4), and with electrical Rx Pam4 signals 230. In an embodiment, the microcontroller 206 may be coupled by RDL 212 to the Tx and Rx CDR's 204, 204′, in an embodiment.

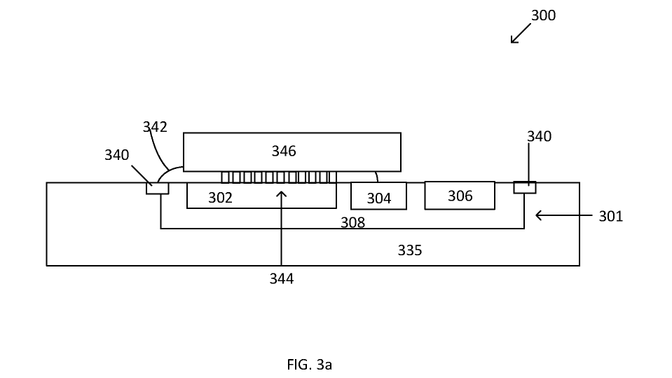

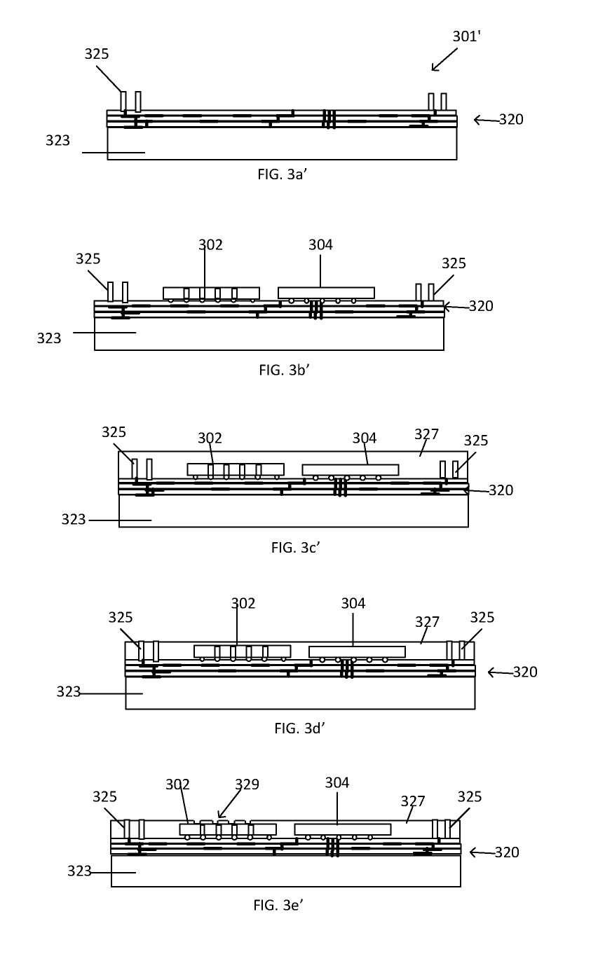

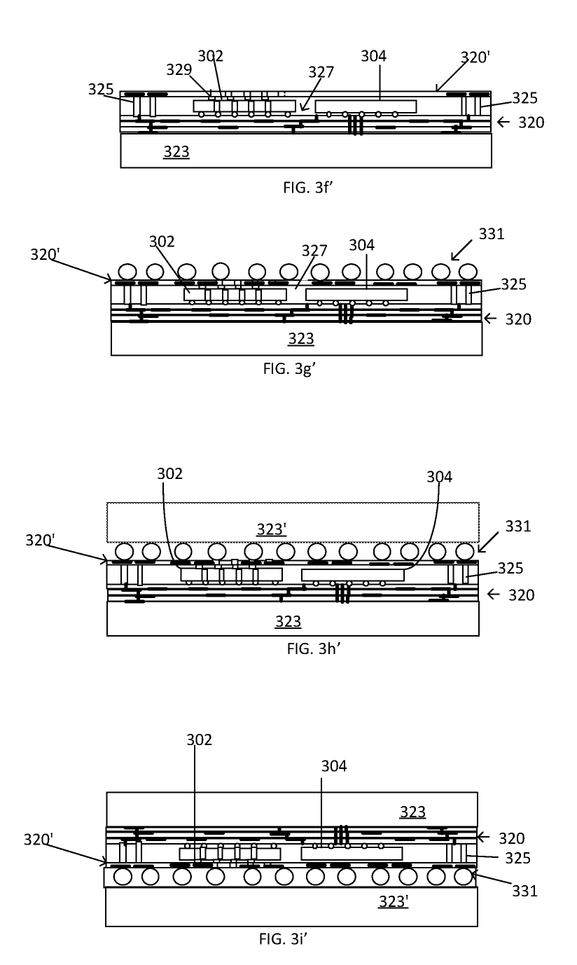

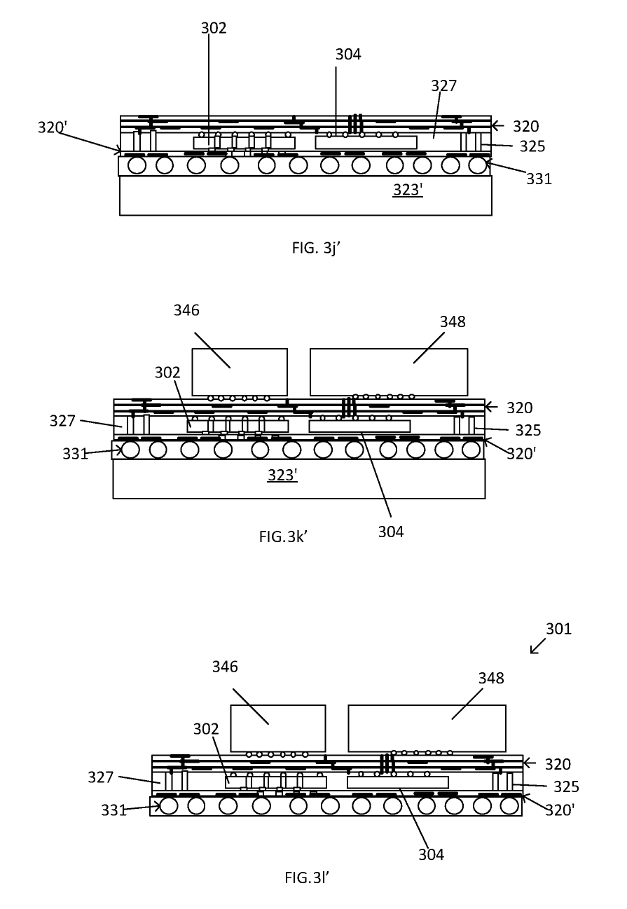

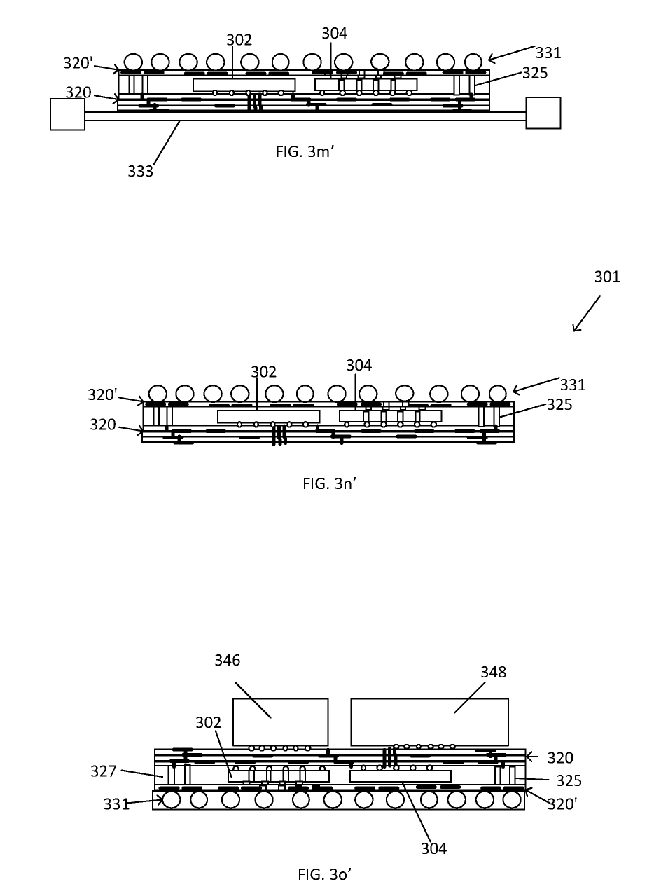

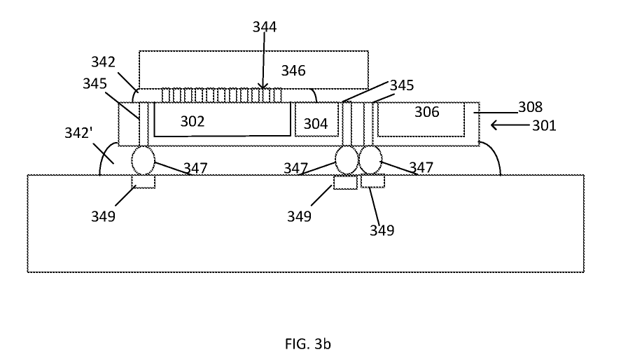

FIGS. 3a-3b depict cross sectional views of embodiments of package integration by optics die stacking on eWLB structures/UIC 301. In FIG. 3a, a package structure/optical module 300 depicts eWLB structure 301 that may be electrically coupled to a substrate 335, wherein the eWLB/UIC 301 may be embedded within the substrate 335. A driver die 302, a Rx die 304, and a CDR die 306, may be disposed on and may be embedded within a mold compound 308 within the substrate 335. In other embodiments, other types of suitable die may be included within the mold compound 308. An optical die STx 346, may be disposed on the driver 302 by conductive interconnect structures, such as solder connections 344. Underfill material, such as an epoxy underfill 342 may surround the solder connections 344 in an embodiment. Contact structures 340 may be disposed on a top surface of the substrate 335, and may electrically couple the substrate 335 with the UIC 301.

FIGS. 3a′-FIG. 3o′ depict cross sectional views of a method of forming the package structure/optical module of FIG. 3a, by embedded wafer level processing methods, wherein a wafer, such as a mold wafer, may be repopulated by a plurality of UIC structures. FIG. 3a′ depicts a portion of a carrier wafer 323 comprising a redistribution layer (RDL) 320 disposed thereon, wherein the redistribution layer 320 comprises metal routing layers, such as copper traces/interconnect structures, separated by dielectric material. Post structures 325, which may comprise copper interconnect structures, in an embodiment, may be disposed on a top surface of the redistribution layer 320. In an embodiment, the posts 325 may be disposed on each of the edges portions of the carrier wafer 320. In FIG. 3b′, at least one die (shown as die 302 and die 304, which may comprise Tx and driver die, for example, but may comprise any suitable die functions/die numbers according to the particular application) may be electrically and physically coupled with the RDL layer 320. In an embodiment, the die 302, 304 may be attached with an active surface (comprising circuitry) face down and interfacing with the RDL 320.

In FIG. 3c′, a mold material 327 may be formed around the die 302, 3024 such that the die may be completely embedded in the mold compound 327, which may comprise an epoxy material, for example. In FIG. 3d′, the mold compound 327 may be polished down to expose a back side of the die 302, 304. The mold may be polished using a chemical mechanical polishing (CMP) process, and/or a grinding process, for example. In FIG. 3e′, vias 329 may be formed on a surface of at least one of the die 302, 304. In an embodiment, the vias 329 may comprise openings in the mold compound 327 and may be optionally formed, according to the particular design requirements.

In FIG. 3f, a second RDL layer 320′ may be formed on the vias 329, and over the first RDL 320. In FIG. 3g′, a plurality of solder balls 331, may be attached on the second RDL layer 320′. The solder balls may comprise a plurality of C4 bumps 331, in an embodiment. In FIG. 3h′, a second carrier wafer 323′ may be attached to the conductive bumps 331, and the first carrier wafer 323 may be flipped over (FIG. 3i′), and the first carrier wafer 323 may be removed (FIG. 3j′). In FIG. 3k′, at least one optical die 346, 348 may be attached to the first RDL 320. The optical die may comprise any suitable optical die, such as Stx and/or SRx die, for example. In FIG. 3l′, the second carrier wafer 323′ may be removed, and the remaining UIC structures may be diced from the wafer into separate units 301, such as UIC units, and any adhesive may be removed.

FIGS. 3m′-3o′ depict an embodiment wherein the first carrier is initially removed after ball attach. In FIG. 3m′, the first RDL 320 may be placed on an adhesive material 333, such as a dicing tape, and the first carrier 323 may be removed. The separate UIC components may be diced from the wafer (FIG. 3n′), and optical die may be attached to the UIC (FIG. 3o′).

FIG. 3b depicts a package structure/optical module 300 wherein the eWLB 301 may be coupled to the substrate 335 by using a through mold via (TMV) 345 that may extend through the mold compound 308 of the eWLB structure 301. In an embodiment, the substrate 35 may comprise a printed circuit board, or any other type of suitable substrate board. Optics die, such as the STx die 346, may be coupled to the eWLB/universal IC 301 with solder connections 344 that may be surrounded by an underfill material 342, in an embodiment. A driver die 302, Rx CDR die 304, and microprocessor die 306 may be disposed within the mold compound in the eWLB 301. The through mold vias 345 may be physically and electrically coupled to conductive/solder structures 347 that may be disposed on the substrate 335, and may be surrounded by an underfill material 342′. The solder structures/balls 347 may be electrically and physically coupled to contact structures 349, such as bond pads, that may be disposed on/within the substrate 335.

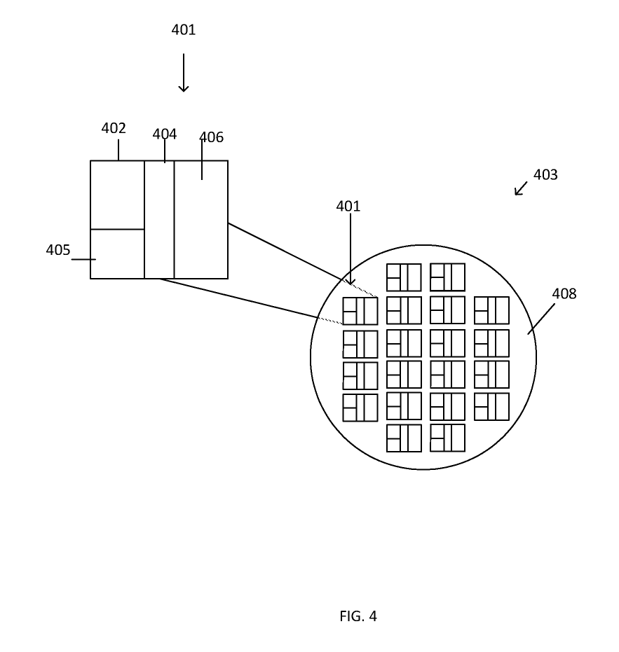

FIG. 4 depicts a wafer 403, which may comprise a mold wafer, and may comprise a reconstituted wafer, in an embodiment. The reconstituted wafer 403 may be formed by selecting a plurality of microelectronic die, that may be known and/or tested to be good (e.g., functioning). The die may be taken from a wafer from which the die were formed (e.g., by dicing a silicon wafer) and the die may be placed onto a carrier using adhesive foil, for example. An electrically insulating layer, such as a molding layer/compound 408, may be formed around the die (such as the driver die 402, the CDR die 404, the microprocessor die 406 and the TIA die 405). Subsequent processing steps, such as the formation of RDL structures, may be performed on a wafer 403 level, such as on a universal IC wafer. Multiple units of a UIC 401 may be disposed on the wafer 403, and may undergo wafer level processing, such as according to any of the FIGS. 3a′-3o′, for example, to form portions of an optics module.

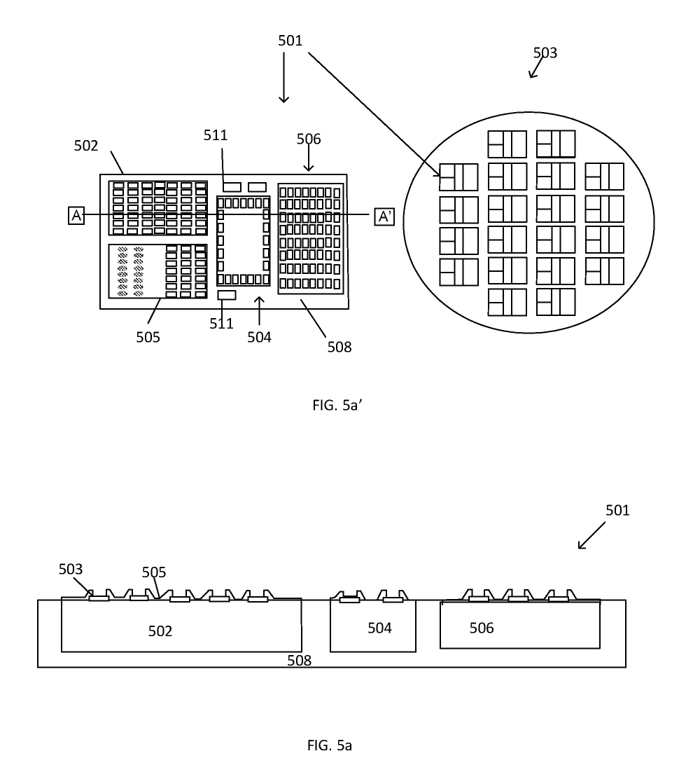

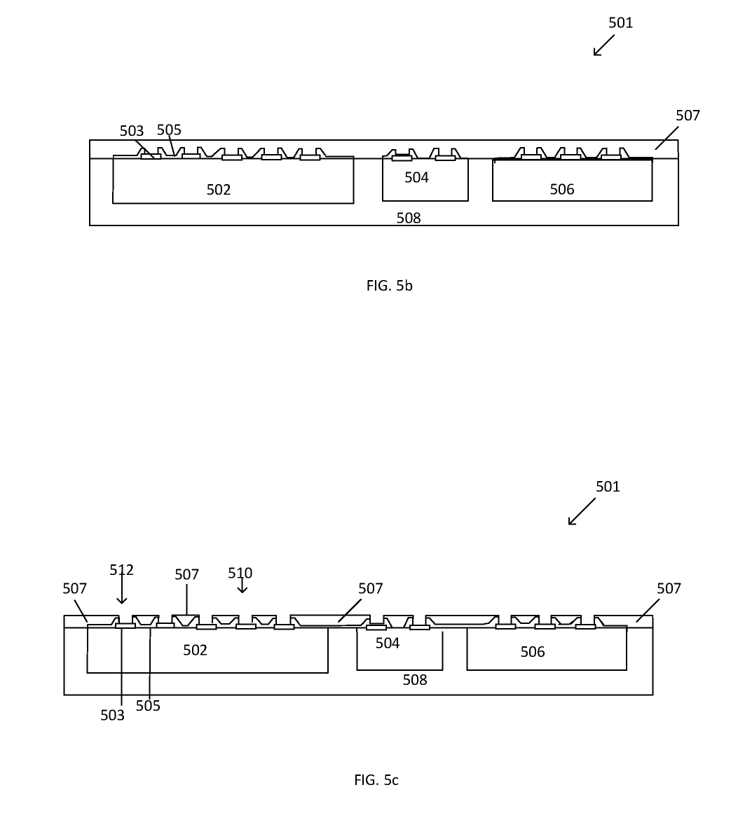

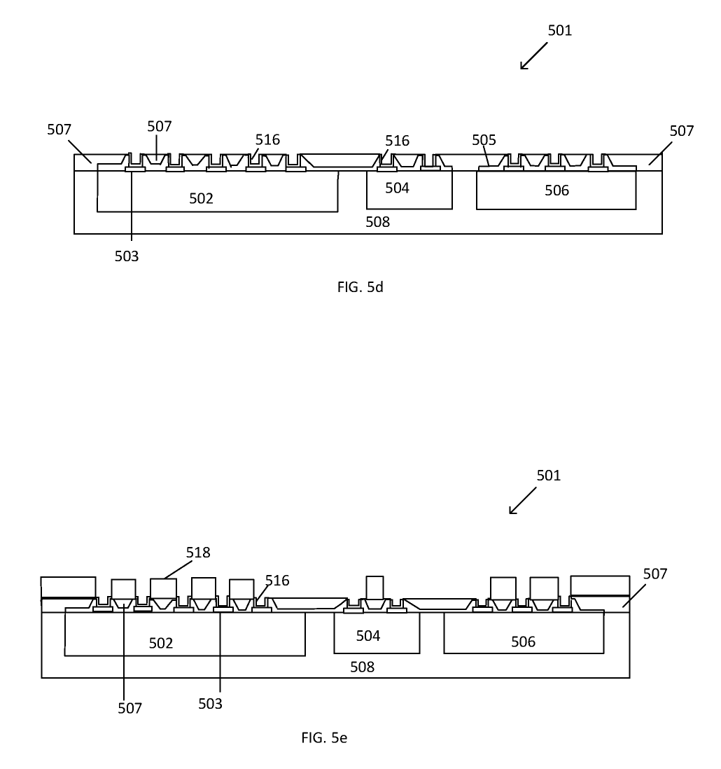

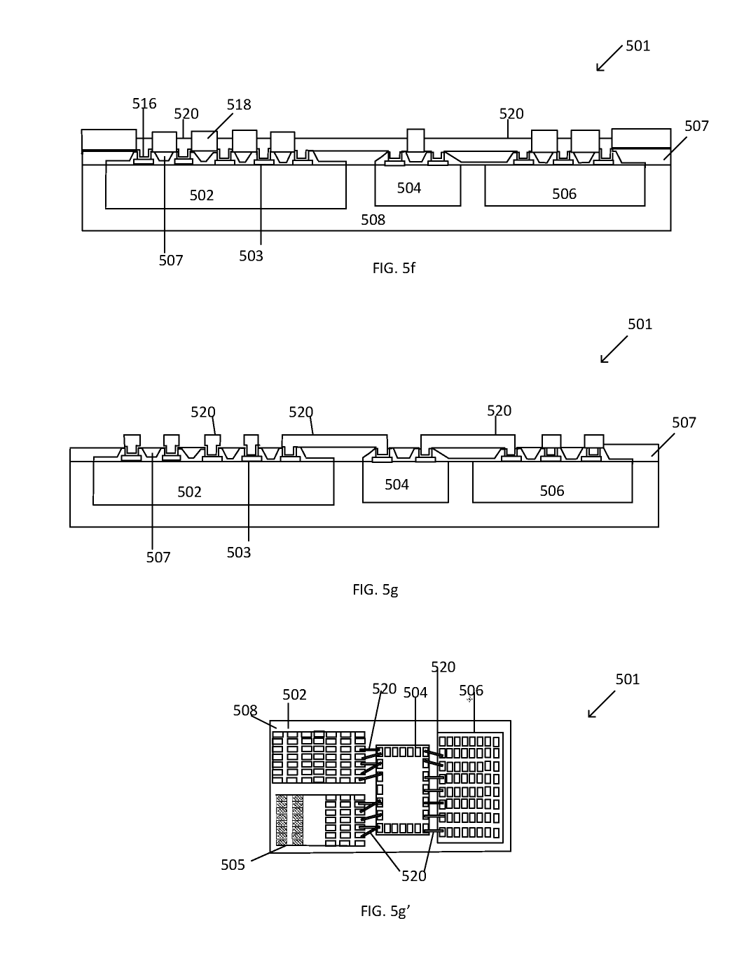

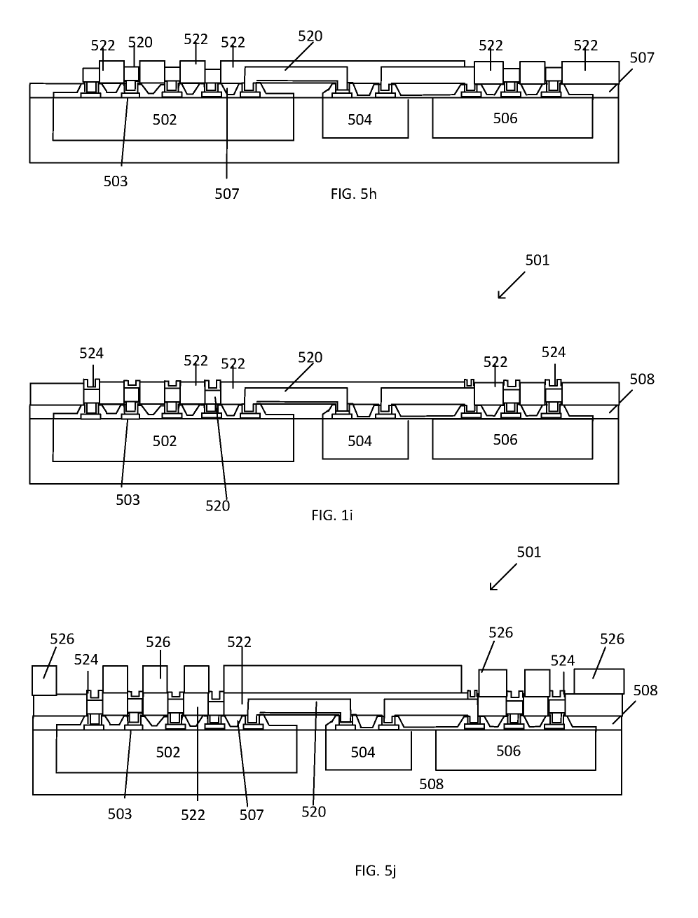

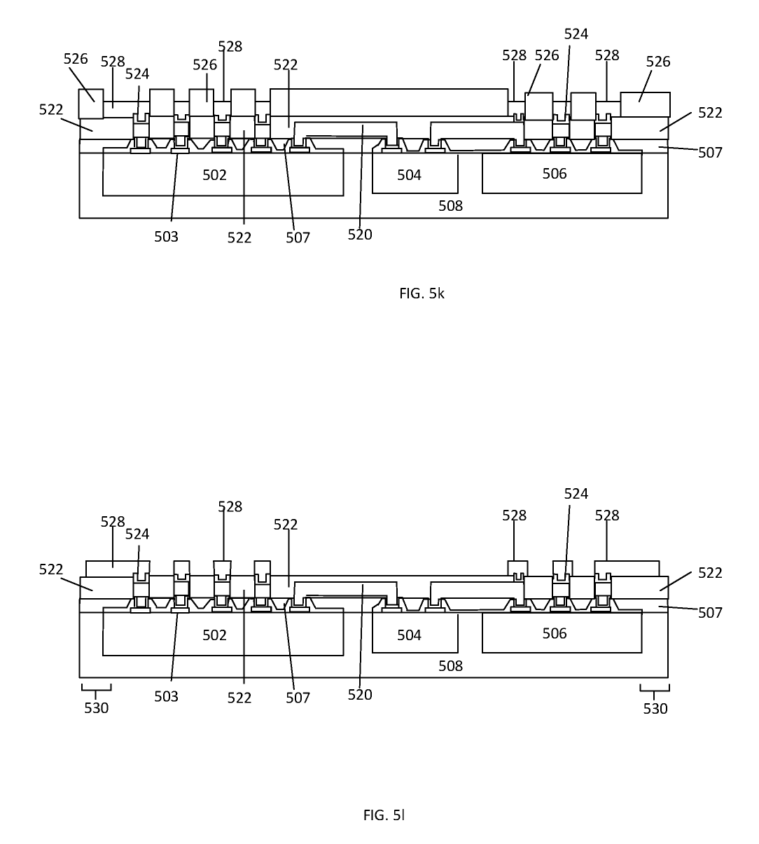

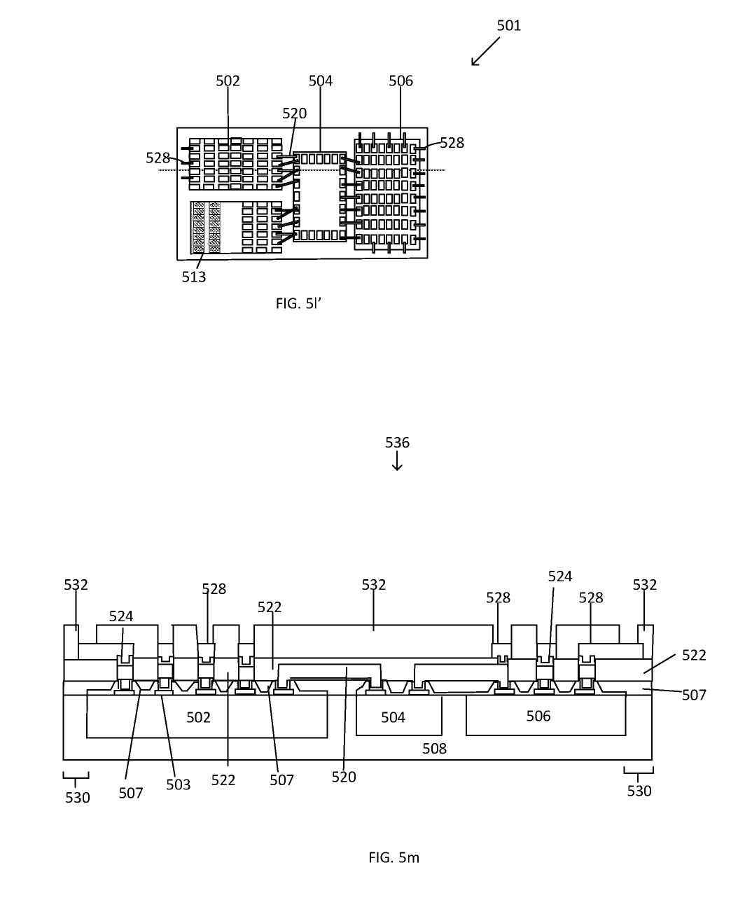

FIG. 5a′ depicts a top view of a wafer 503, which may comprise a reconstituted wafer, in an embodiment. The reconstituted wafer 503 may comprise a wafer wherein good die from a first wafer may be singulated and sawed from the first wafer, and then picked and placed onto a carrier, and then an electrically insulating layer, such as a molding compound 508, for example, epoxy molding compound (EMC) may be formed around the die, such as the driver die 502, CDR die, microprocessor die 506, and TIA die 505, that are disposed on the wafer 503. A group of die may comprise the eWLB structure 501, and a plurality of eWLB structures 501 may be disposed on the wafer 503.

FIG. 5a depicts a cross section of a portion of the eWLB structure 501 (which may comprise a UIC), through the line A-A′ of FIG. 5a′. Contacts 503 and dielectric 505 are disposed on the driver die 502, CDR die, and the microprocessor die 506, wherein the substrate 508 may comprise EMC. The contacts 503 may comprise any suitable conductive material, such as copper for example, and the dielectric structures 505 may comprise silicon dioxide, or any other type of insulating material.

FIG. 5b depicts a first level/layer of passivation 507 that may be formed on the contacts 503 and the dielectric isolation structures 505. The passivation layer 507 may comprise a dielectric material, such as silicon dioxide, or any suitable dielectric material, and may comprise such thickness as 1000 to 50,000 angstroms, for example. In an embodiment the first layer of passivation 507 may comprise a polymer material such as polyimide (PI) or polybenzobisoxazole (PBO)). FIG. 5c depicts the patterning of the passivation layer 507, wherein portions of the passivation layer 507 is removed by a removal process, such as a wet/dry etch for example, to expose the contact structures 503, but the passivation layer 507 remains on the dielectric material 505 adjacent the contacts 503. Openings 512 are formed that expose the contact 503 surface.

In FIG. 5d, a seed layer 516 may be formed on the contact structures 503, and in an embodiment, the seed layer 516 may be selectively formed on the contacts 503. In other embodiments, the seed layer 516 may be formed in a blanket deposition, and may be removed from the passivation layer 507, by an etching process, for example. In an embodiment, the seed layer 516 may comprise a conductive material, such as copper and/or alloys of copper, and may comprise a thickness of about 1 micron to about 10 microns. In FIG. 5e, a resist material 518, such as a photoresist, may be formed/coated and developed/patterned on the passivation layer/pads 507 and may not be formed on the seed layer 516. In FIG. 5f, a conductive material 520 may be formed on the seed layer 516. In an embodiment, the conductive material 520 may comprise a redistribution layer (RDL). The redistribution layer 520 may include a plurality of redistribution lines, at least some of which may extend beyond the boundaries of the die within the molding 508, such as the driver die 502, the TIA die 504 and the microprocessor die 506, die. In an embodiment, the redistribution layer 520 may comprise a copper material, and may be formed by an electroplating process. In another embodiment, the redistribution layers may be applied using various thin film and/or printed circuit board (PCB) deposition processes, including sputtering and plating, electroless seed layer application, electroplating, printing, and/or other deposition processes.

In FIG. 5g, the resist 518 (and possibly any seed layer on the dielectric material 107) may be removed from the dielectric material 507. FIG. 5g′ depicts a top view of the RDL 520 electrically and physically coupling the die (Tx 502, CDR 504, TIA 505, and the microprocessor 506), to each other. In FIG. 5h, a second passivation layer 522, which may comprise a polymer material, may be formed and patterned so that is disposed on the passivation material 507 in between the exposed surfaces of the RDL layer 520, that are adjacent the second passivation layer 522. In FIG. 5i, a second seed layer 524 may be formed and patterned on the RDL 520.

In FIG. 5j, a resist material 526 may be disposed on the second passivation layer 522 adjacent the second seed layer 524. In FIG. 5k, conductive material 528, such as copper for example, may be formed on the second seed layer 524 and portions of the second passivation layer 522. The resist material 526 may be removed (FIG. 5l), and a portion of the conductive material 528, which may comprise bond pads 528, may be disposed on a fan out portion 530 of the molding 508 (additionally shown in FIG. 5l′, top view). A third layer of planarization 532 may be formed on portions of the conductive material 528, and a pad surface finish process 536 may be applied to exposed portions of the conductive material 528 (FIG. 5m). In an embodiment, the surface finish process 536 may comprise a plating process, such as a nickel gold plating process, for example. Any suitable surface finish may be applied to the exposed portions of the conductive material, such as nickel palladium gold, or other suitable finishes, depending upon the particular application. After the finish process 536 is applied, the portion of the individual die 501 may be diced from the reconstituted wafer 501. Additionally, the backside of the molding 508 may be thinned by a grinding or polishing process, to open the backside of the individual die.

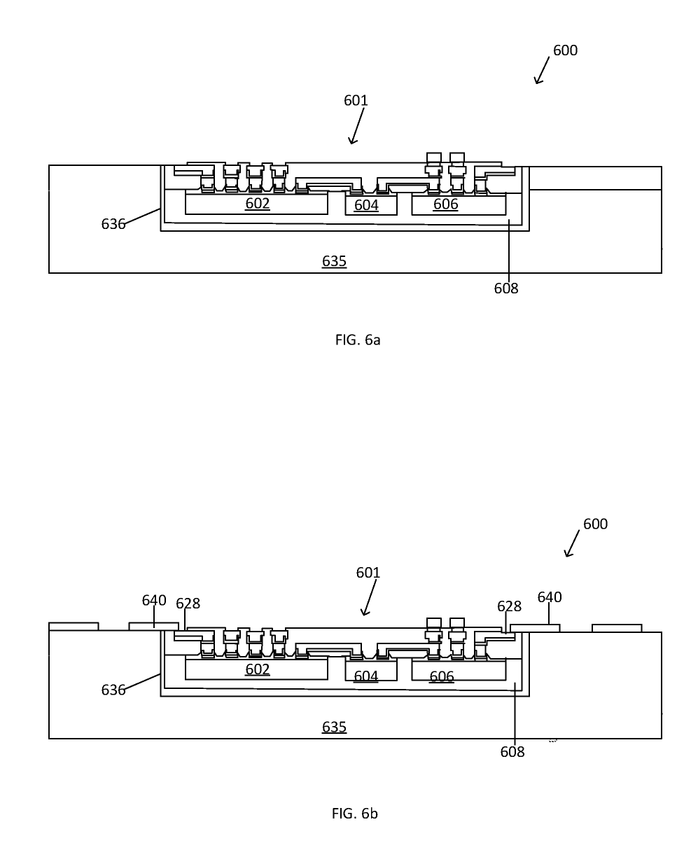

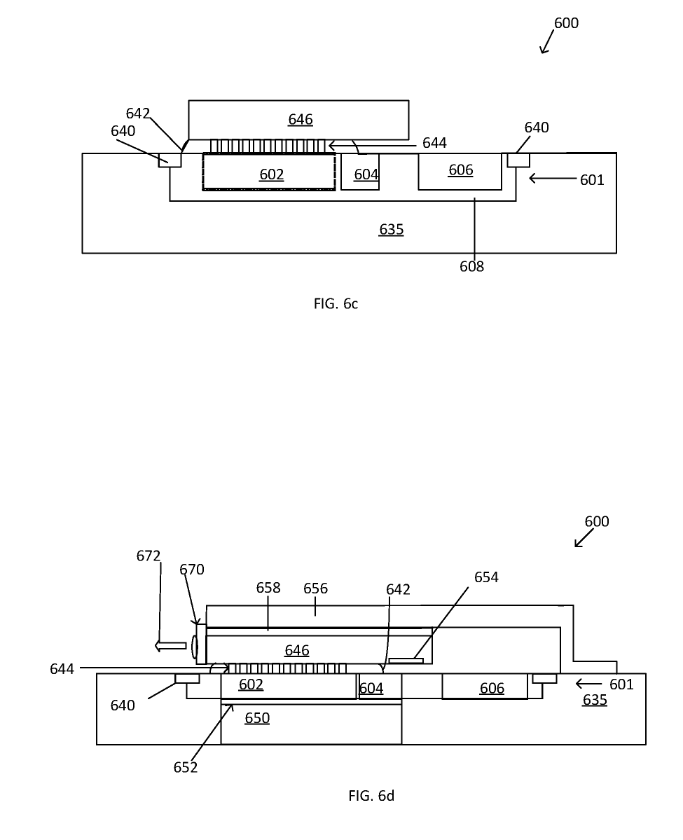

FIG. 6a depicts a package structure 600, wherein a die structure 601, such as an embedded wafer level ball grid array die structure 501, or any other die, such as a system on a chip, according to the embodiments herein, is placed in a cavity of a substrate 635. The die 601, which may comprise an eWLB structure/UIC, may comprise a driver die 602, a CDR die 604 and a microprocessor and management die 606, and may additionally comprise any other suitable die, according to the particular design requirements. The die 601 may comprise conductive and dielectric/insulating material configured to route signals within the die 601 and to external structures/devices. The die 601 may further comprise passive components on a top surface of the die 601, and may be disposed within a mold material 608, such as an EMC material, for example. A liner, 636, which may comprise a dielectric material in an embodiment, may line an outer surface of the die 601 within the substrate 635. The substrate 635 may comprise any suitable substrate, such as a PCB board, or any other type of board or substrate capable of receiving the die 601.

A metallization trace/conductive material 640 may be formed on a top surface of the substrate 635, and may electrically and physically couple to at least one conductive trace 628 disposed on the die 601. The trace 640 may electrically couple the eWLB die 601 to the substrate 635. FIG. 6c depicts the package structure 600 comprising the embedded die 601 (comprising driver, CDA, and microprocessor 602, 604, 606, for example) further comprising optical die STx 646 and SRx (adjacent to the STx, not shown) onto the substrate 635. Underfill material 642 may comprise suitable underfill material such as epoxy material, and may surround conductive interconnect structures 644, which may couple the STx with the die 601 and the substrate 635. In an embodiment, the optical die 646 may comprise a flip chip optical die.

In another embodiment, the package structure 600 may comprise the die 601, which may comprise driver 602, CDR 604 and universal plus management 606, which may be embedded in a mold compound 608 and may comprise an eWLB die (FIG. 6d). A thermal slug 650 may be physically coupled with the die 601 by a thermal die attach layer/thermal interface material 652, in an embodiment, the thermal slug 650 and the thermal die attach material 652 may be disposed within the substrate 635, wherein the die may be embedded in a cavity within the substrate 635. A hybrid laser (HL) array 654 may be disposed within a STx 646 coupled to the die 601, and a thermal interface material 658 may be disposed between the STx 646 and a thermal solution 656, such as an integrated heat spreader for example. The thermal slug 650 may provide a thermal path on the bottom side of the substrate 635 through the thermal interface material 652. The thermal solution 656 provides a thermal path on the top side of the package structure 600, which may include a housing, through the thermal interface material 658 and thermal solution 656. An optical alignment structure 670 may provide functionality with which to direct an optical signal 672. The package 600 of FIG. 6d. is an embodiment of a configuration comprising thermal paths (top and bottom direction, and electrical stacking on eWLB UIC integration, and an optical path.

The embodiments herein enable the utilization/integration of a universal IC based modular photonic engine incorporating a UIC eWLB platform. Die embedding assembly design/process is realized using a 3D photonic engine platform. The photonic engine block of the embodiments herein can be employed with pluggable quad small form factor (QSFP)-double density (DD) devices, such as with a 400 Gbps-DD optical module, or with embedded optics on board or central processing unit (CPU) field programmable gate array (FPGA)/switch co-packaging architectures. The embodiments herein provide high speed, high thermal dissipation, compact, reliable and integrated package solutions for silicon photonic devices in chip to chip optical interconnect structures.

The photonic engine modular package design/platform of the embodiments herein are based on silicon photonics core technology, such as integrated laser Tx and integrated lens Rx and universal SoC IC's based on eWLB integration, which achieves compact size, high thermal dissipation and electronic/optical interconnection. The embodiments herein are extremely beneficial for high performance computing, data center, board to board, memory to CPU, switch/FPGA, chip to chip interconnects and optical memory extension. Packaging processing, fabrication costs and mechanical reliability/thermal dissipation issues are greatly improved by utilizing the embodiments herein.

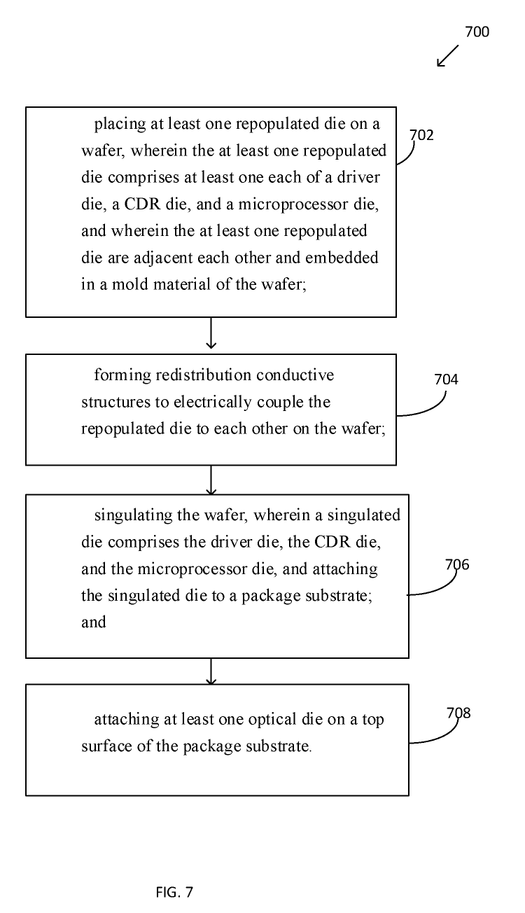

FIG. 7 depicts a method 700 according to embodiments herein. At step 702, at least one repopulated die may be placed on a wafer, wherein the at least one repopulated die comprises at least one each of a driver die, a CDR die, and a microprocessor die, and wherein the at least one repopulated die are adjacent each other and embedded in a mold compound of the mold wafer. In an embodiment, the wafer may comprise a reconstituted wafer, and the at least one repopulated die may comprise electrical die capable of integrating with a photonics module assembly. At step 704, redistribution conductive structures may be formed to electrically couple the repopulated die to each other on the wafer. In an embodiment, the redistribution conductive structures may comprise RDL structures formed by an eWLB process. At step 706, the wafer may be singulated, wherein a singulated die comprises the driver die, the CDR die, and the microprocessor die, and the singulated die may be attached to a package substrate. The singulated die may comprise a UIC die in an embodiment, and may be embedded in a molding compound. In an embodiment, the singulated die may be attached by embedding the die in the substrate or by using through mold vias, wherein the singulated die is disposed on a top surface of the package substrate. At step 708, at least one optical die may be attached on a top surface of the package substrate. In an embodiment, the at least one optical die may be electrically and physically coupled to the singulated die. The singulated die may further be electrically connected with an optical alignment apparatus.

The structures of the embodiments herein may be coupled with any suitable type of structures capable of providing electrical communications between a microelectronic device, such as a die, disposed in package structures, and a next-level component to which the package structures herein may be coupled (e.g., a circuit board). The device/package structures, and the components thereof, of the embodiments herein may comprise circuitry elements such as logic circuitry for use in a processor die, for example. Metallization layers and insulating material may be included in the structures herein, as well as conductive contacts/bumps that may couple metal layers/interconnects to external devices/layers. In some embodiments the structures may further comprise a plurality of dies, which may be stacked upon one another, depending upon the particular embodiment. In an embodiment, a die(s) may be partially or fully embedded in a package structure.

The various embodiments of the device structures included herein may be used for system on a chip (SOC) products, and may find application in such devices as smart phones, notebooks, tablets, wearable devices and other electronic mobile devices. In various implementations, the package structures herein may be included in a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder, and wearable devices. In further implementations, the package devices herein may be included in any other electronic devices that process data.

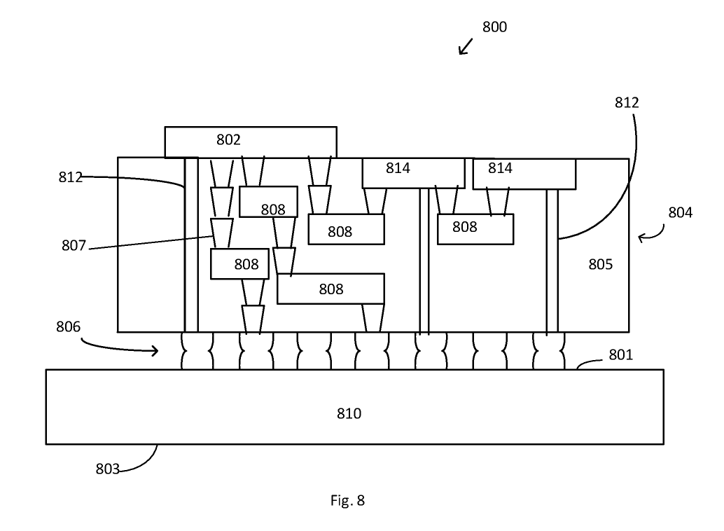

Turning now to FIG. 8, illustrated is an embodiment of a computing system 800. The system 800 includes a mainboard 802 or other circuit board. Mainboard 802 includes a first side 801 and an opposing second side 803, and various components may be disposed on either one or both of the first and second sides 801, 803. In the illustrated embodiment, the computing system 800 includes at least one die 802, disposed on a surface (such as on a top or bottom or side surface) of the substrate 804, such as a package substrate comprising the UIC die of the various embodiments herein. The substrate 804 may comprise an interposer 804, for example.

The substrate 804 may comprise various levels of conductive layers 808, 814 for example, which may be electrically and physically connected to each other by via structures 807. The substrate 504 may further comprise through substrate vias 812. Dielectric material 805 may separate/isolate conductive layers from each other within the substrate 804. Joint structures 806 may electrically and physically couple the substrate 804 to the board 802. The computing system 800 may comprise any of the embodiments described herein. In an embodiment, the substrate may comprise a multi-chip package substrate in an embodiment.

System 800 may comprise any type of computing system, such as, for example, a hand-held or mobile computing device (e.g., a cell phone, a smart phone, a mobile internet device, a music player, a tablet computer, a laptop computer, a nettop computer, etc.). However, the disclosed embodiments are not limited to hand-held and other mobile computing devices and these embodiments may find application in other types of computing systems, such as desk-top computers and servers.

Mainboard 810 may comprise any suitable type of circuit board or other substrate capable of providing electrical communication between one or more of the various components disposed on the board. In one embodiment, for example, the mainboard 810 comprises a printed circuit board (PCB) comprising multiple metal layers separated from one another by a layer of dielectric material and interconnected by electrically conductive vias. Any one or more of the metal layers may be formed in a desired circuit pattern to route—perhaps in conjunction with other metal layers—electrical signals between the components coupled with the board 810. However, it should be understood that the disclosed embodiments are not limited to the above-described PCB and, further, that mainboard 810 may comprise any other suitable substrate.

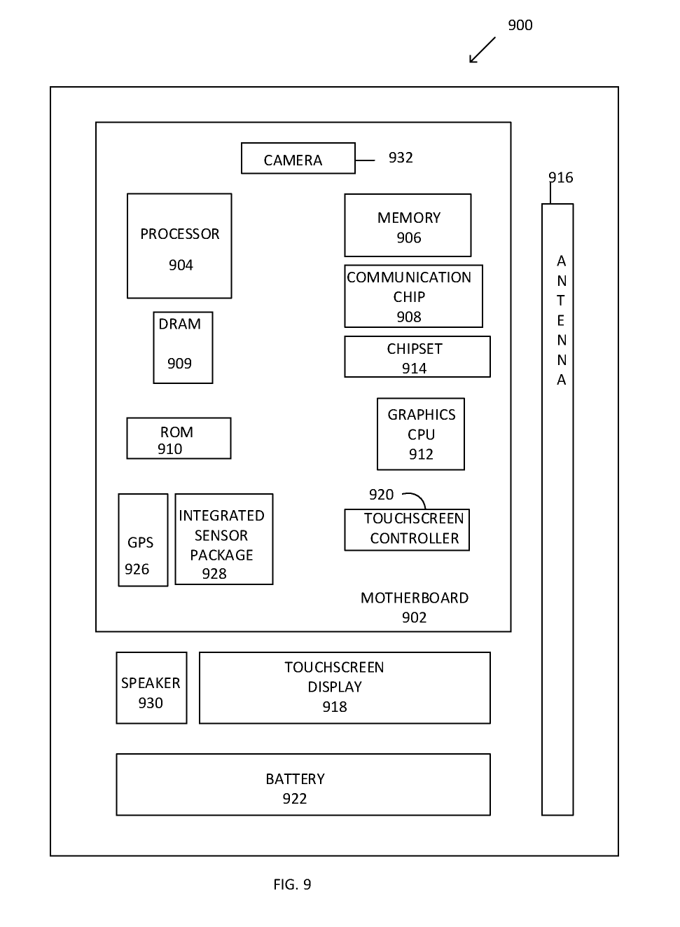

FIG. 9 is a schematic of a computing device 900 that may be implemented incorporating embodiments of the package structures/optical modules described herein. For example, any suitable ones of the components of the computing device 900 may include, or be included in, package structures comprising the UIC die integrated with a photonics module of the various embodiments disclosed herein. In an embodiment, the computing device 900 houses a board 902, such as a motherboard 902 for example. The board 902 may include a number of components, including but not limited to a processor 904, an on-die memory 906, and at least one communication chip 908. The processor 904 may be physically and electrically coupled to the board 902. In some implementations the at least one communication chip 908 may be physically and electrically coupled to the board 902. In further implementations, the communication chip 908 is part of the processor 904.

Depending on its applications, computing device 900 may include other components that may or may not be physically and electrically coupled to the board 902, and may or may not be communicatively coupled to each other. These other components include, but are not limited to, volatile memory (e.g., DRAM) 909, non-volatile memory (e.g., ROM) 910, flash memory (not shown), a graphics processor unit (GPU) 912, a chipset 914, an antenna 916, a display 918 such as a touchscreen display, a touchscreen controller 920, a battery 922, an audio codec (not shown), a video codec (not shown), a global positioning system (GPS) device 926, an integrated sensor 928, a speaker 930, a camera 932, an amplifier (not shown), compact disk (CD) (not shown), digital versatile disk (DVD) (not shown), and so forth). These components may be connected to the system board 902, mounted to the system board, or combined with any of the other components.

The communication chip 908 enables wireless and/or wired communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 908 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond.

The computing device 900 may include a plurality of communication chips 908. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others. The term “processor” may refer to any device or portion of a device that processes electronic data from registers and/or memory to transform that electronic data into other electronic data that may be stored in registers and/or memory.

In various implementations, the computing device 900 may be a laptop, a netbook, a notebook, an ultrabook, a smartphone, a tablet, a personal digital assistant (PDA), an ultra mobile PC, a wearable device, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

Embodiments of the package structures described herein may be implemented as a part of one or more memory chips, controllers, CPUs (Central Processing Unit), microchips or integrated circuits interconnected using a motherboard, an application specific integrated circuit (ASIC), and/or a field programmable gate array (FPGA).

### EXAMPLES

Example 1 is a microelectronic package structure comprising: a device structure comprising at least one die at least partially embedded in a mold material; a package substrate, wherein the device structure is at least partially embedded in the package substrate; and at least one optical die disposed on the package substrate, wherein the at least one optical die is electrically coupled to the at least one die disposed in the molding compound.

Example 2 includes the microelectronic package structure of example 1, wherein the at least one optical die comprises a die selected from the group consisting of a transmission die, a receiver die, and a clock and data recovery die.

Example 3 includes the microelectronic package structure of example 1 wherein the device structure comprises a system on a chip.

Example 4 includes the microelectronic package structure of example 1 wherein the package structure comprises a portion of a photonic engine block.

Example 5 includes the microelectronic package structure of example 1 wherein the at least one optical die comprises at least one of an optical transmission die or an optical receiver die.

Example 6 includes the microelectronic package structure of example 1 wherein the device structure comprises redistribution layer structures coupling the at least one die.

Example 7 includes the microelectronic package structure of example 1 wherein the device structure is embedded in the package substrate.

Example 8 includes the microelectronic package structure of example 1 wherein the optical die are electrically coupled to an optical alignment assembly.

Example 9 is a microelectronic package structure comprising: a mold material, wherein a plurality of die are embedded in the mold material; a package substrate, wherein the mold material comprising the plurality of die is at least partially embedded in a cavity of the substrate, and wherein a liner is between side and bottom portions of the mold material and the package substrate; at least one optical die disposed on the package substrate; and a thermal solution disposed on a top surface of the optical die.

Example 10 includes the microelectronic package structure of example 9 wherein the thermal solution comprises a heat sink.

Example 11 includes the microelectronic package structure of example 9 wherein the package structure comprises a thermal slug on a bottom surface of the package substrate.

Example 12 includes the microelectronic package structure of example 11 wherein a thermal interface material is disposed between a bottom surface of the substrate and the thermal slug.

Example 13 includes the microelectronic package structure of example 9 wherein an optical alignment assembly is coupled with the at least one optical die.

Example 14 includes the microelectronic package structure of example 9 wherein the plurality of die disposed in the mold material comprise an embedded wafer level ball grid array structure.

Example 15 includes the microelectronic package structure of example 14 wherein the embedded wafer level ball grid array structure comprises a redistribution layer disposed between the at least one die.

Example 16 includes the microelectronic package structure of example 15, wherein the optical die is electrically and physically coupled to a driver die.

Example 17 is a method of forming a microelectronic package structure, comprising: placing at least one repopulated die on a wafer, wherein the at least one repopulated die comprises at least one each of a driver die, a clock and data recovery die, and a microprocessor die, and wherein the at least one repopulated die are adjacent each other and embedded in a mold material; forming redistribution conductive structures to electrically couple the repopulated die to each other on the wafer; singulating the wafer, wherein a singulated die comprises the driver die, the CDR die, and the microprocessor die, and attaching the singulated die to a package substrate; and attaching at least one optical die on a top surface of the package substrate.

Example 18 includes the method of example 17 further comprising wherein the at least one optical die comprise at least one optical transmission die and optical receiver die.

Example 19 includes the method of example 18 wherein the at least one optical transmission die is disposed on the driver die, and the at least one receiver die is disposed on a trans impedance amplification die that is disposed within the mold compound and adjacent a receiver clock and data recovery die.

Example 20 includes the method of example 17 further comprising wherein the clock and data recovery CDR comprises one of a transmission clock and data recovery or a receiver clock and data recovery die.

Example 21 includes the method of example 17 further comprising attaching a heat spreader on the optical die.

Example 22 includes the method of example 17 further comprising attaching a thermal slug onto a bottom portion of the substrate.

Example 23 includes the method of example 17 further comprising attaching an optical alignment apparatus to a portion of the optical die.

Example 24 includes the method of example 17 further comprising wherein attaching the singulated die to the substrate comprises embedding the singulated die into the package substrate.

Example 25 includes the method of example 17 wherein attaching the singulated die to the substrate comprises attaching the singulated substrate to a top surface of the package substrate, and forming through mold vias through the mold material to physically couple the singulated die to the package substrate.

Although the foregoing description has specified certain steps and materials that may be used in the methods of the embodiments, those skilled in the art will appreciate that many modifications and substitutions may be made. Accordingly, it is intended that all such modifications, alterations, substitutions and additions be considered to fall within the spirit and scope of the embodiments as defined by the appended claims. In addition, the Figures provided herein illustrate only portions of exemplary microelectronic devices and associated package structures that pertain to the practice of the embodiments. Thus the embodiments are not limited to the structures described herein.

1-25. (canceled)

26. A microelectronic package structure comprising:
a device structure comprising at least one die at least partially embedded in a mold material;
a package substrate, wherein the device structure is at least partially embedded in the package substrate; and
at least one optical die disposed on the package substrate, wherein the at least one optical die is electrically coupled to the at least one die disposed in the molding compound.

27. The microelectronic package structure of claim 26, wherein the at least one optical die comprises a die selected from the group consisting of a transmission die, a receiver die, and a clock and data recovery die.

28. The microelectronic package structure of claim 26, wherein the device structure comprises a system on a chip.

29. The microelectronic package structure of claim 26, wherein the package structure comprises a portion of a photonic engine block.

30. The microelectronic package structure of claim 26, wherein the at least one optical die comprises at least one of an optical transmission die or an optical receiver die.

31. The microelectronic package structure of claim 26, wherein the device structure comprises redistribution layer structures coupling the at least one die.

32. The microelectronic package structure of claim 26, wherein the device structure is embedded in the package substrate.

33. The microelectronic package structure of claim 26, wherein the optical die are electrically coupled to an optical alignment assembly.

34. A microelectronic package structure comprising:
a mold material, wherein a plurality of die are embedded in the mold material;
a package substrate, wherein the mold material comprising the plurality of die is at least partially embedded in a cavity of the substrate, and wherein a liner is between side and bottom portions of the mold material and the package substrate;
at least one optical die disposed on the package substrate; and
a thermal solution disposed on a top surface of the optical die.

35. The microelectronic package structure of claim 34, wherein the thermal solution comprises a heat sink.

36. The microelectronic package structure of claim 34, wherein the package structure comprises a thermal slug on a bottom surface of the package substrate.

37. The microelectronic package structure of claim 36, wherein a thermal interface material is disposed between a bottom surface of the substrate and the thermal slug.

38. The microelectronic package structure of claim 34, wherein an optical alignment assembly is coupled with the at least one optical die.

39. The microelectronic package structure of claim 34, wherein the plurality of die disposed in the mold material comprise an embedded wafer level ball grid array structure.

40. The microelectronic package structure of claim 39, wherein the embedded wafer level ball grid array structure comprises a redistribution layer disposed between the at least one die.

41. The microelectronic package structure of claim 40, wherein the optical die is electrically and physically coupled to a driver die.

42. A method of forming a microelectronic package structure, comprising:
placing at least one repopulated die on a wafer, wherein the at least one repopulated die comprises at least one each of a driver die, a clock and data recovery die, and a microprocessor die, and wherein the at least one repopulated die are adjacent each other and embedded in a mold material;
forming redistribution conductive structures to electrically couple the repopulated die to each other on the wafer;
singulating the wafer, wherein a singulated die comprises the driver die, the CDR die, and the microprocessor die, and attaching the singulated die to a package substrate; and
attaching at least one optical die on a top surface of the package substrate.

43. The method of claim 42 further comprising wherein the at least one optical die comprise at least one optical transmission die and optical receiver die.

44. The method of claim 43, wherein the at least one optical transmission die is disposed on the driver die, and the at least one receiver die is disposed on a trans impedance amplification die that is disposed within the mold compound and adjacent a receiver clock and data recovery die.

45. The method of claim 42 further comprising wherein the clock and data recovery CDR comprises one of a transmission clock and data recovery or a receiver clock and data recovery die.

46. The method of claim 42 further comprising attaching a heat spreader on the optical die.

47. The method of claim 42 further comprising attaching a thermal slug onto a bottom portion of the substrate.

48. The method of claim 42 further comprising attaching an optical alignment apparatus to a portion of the optical die.

49. The method of claim 42 further comprising wherein attaching the singulated die to the substrate comprises embedding the singulated die into the package substrate.

50. The method of claim 42 wherein attaching the singulated die to the substrate comprises attaching the singulated substrate to a top surface of the package substrate, and forming through mold vias through the mold material to physically couple the singulated die to the package substrate.
